(19) United States
(12) Patent Application Publication
(10) Pub. No.: US 2011/0170254 A1
(43) Pub. Date: Jul. 14, 2011

(54) Laptop computer display

(75) Inventors: Po-Feng Chuang, Taoyuan County (TW); Ming-Feng Hsu, Changhua County (TW)

(73) Assignee: Quanta Computer Inc., Taoyuan Shien (TW)

(21) Appl. No.: 12/801,746

(22) Filed: Jun. 23, 2010

(30) Foreign Application Priority Data
Jan. 12, 2010 (TW) 99200584

(51) Int. Cl. G06F 1/16; H05K 5/00

(52) U.S. Cl. 361/679.27

(57) ABSTRACT

A laptop computer display is disclosed, which includes a cover, a panel, a cushion, a bezel, and several screws. The inner surface of the cover is disposed with several L-shaped rubber structures. The panel is coupled by the L-shaped rubber structure. The bezel has an opening to expose the panel. The cushion is disposed between the bezel and the panel. The bezel and the cover are screwed by the screws.

### RELATED APPLICATIONS

This application claims priority to Taiwan Application Serial Number 99200584, filed Jan. 12, 2010, which is herein incorporated by reference.

### BACKGROUND

1. Field of Invention

The present invention relates to a display. More particularly, the present invention relates to a laptop computer display.

2. Description of Related Art

Liquid crystal displays have many advantages including high definition resolutions, small volumes, light, low voltage drive, low power consumption, and a broad range of applications, etc. Therefore, liquid crystal displays are already broadly used in consumer electronic devices or computer products, such as portable televisions, cellular phones, camcorders, laptop computers, desktop displays, projection televisions, etc., thereby becoming the main stream for displays.

However, the reliability requirement of the electronic device becomes higher and higher. How to satisfy the requirement of preventing the laptop computer display crashing from unwanted falling has become a problem.

### SUMMARY

An aspect of the invention provides a laptop computer display, which includes a cover having a plastic casing with an inner surface and an outer surface, and a plurality of L-shaped plastic structures disposed on the inner surface, a rubber layer disposed on the outer surface, and plural rubber structures disposed on the inner surface. The rubber structures include plural L-shaped rubber structures formed inside the L-shaped plastic structures. The laptop computer display includes a display panel disposed on the inner surface. The L-shaped rubber structures are disposed corresponding to the corners of to the display panel to couple to the display panel. The laptop computer display has a bezel with an opening to expose the display panel, a cushion disposed between the cover and the bezel, and plural screws for screwing the cover and the bezel.

The laptop computer display further includes two panel brackets disposed at opposite sides of the display panel, wherein each panel bracket has two bending portions formed on opposite ends to couple to the L-shaped plastic structures. A gap is formed between each panel bracket and the display panel. Each panel bracket includes at least one screwing portion, and the screws screw the panel brackets on the cover. The rubber structures include a plurality of rubber bars disposed on the inner surface and touching the display panel. The rubber structures connect to the rubber layer.

Another aspect of the invention is a laptop computer display, which includes a cover having a plastic casing with an inner surface and an outer surface, plural L-shaped plastic structures disposed on the inner surface, and plural rubber structures disposed on the inner surface. The rubber structures include plural L-shaped rubber structures formed inside the L-shaped plastic structures. The laptop computer display includes a display panel disposed on the inner surface. The L-shaped rubber structures are disposed corresponding to plural corners of the display panel to couple to the display panel. The laptop computer includes a bezel having an opening to expose the display panel, and plural screws for screwing the cover and the bezel.

The laptop computer display includes two panel brackets disposed on opposite sides of the display panel, wherein each panel bracket has two bending portions formed on opposite ends to couple to the L-shaped plastic structures, and a gap is formed between each panel bracket and the display panel. The rubber structures include plural rubber bars disposed on the inner surface and touching the display panel. The laptop computer display further includes a rubber layer disposed on the outer surface of the plastic casing, wherein the rubber structures connect to the rubber layer.

The rubber layer and the rubber bars formed on the cover can absorb the external shock. The rubber bars and the cushion can be the damping structures of the display panel. The display panel can be fixed by coupling to the L-shaped plastic structures and the L-shaped rubber structures. The L-shaped rubber structures can provide shockproof ability. The cushion disposed between the bezel and the display panel can provide shockproof ability and seal the space between the bezel and the display panel for waterproof. The rubber layer, the L-shaped rubber structures, and the rubber bars are formed integral via the holes of the cover to enhance the shockproof ability of the laptop computer display.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an explosion diagram of an embodiment of the laptop computer display of the invention;

FIG. 2A is a front view of the cover of the embodiment in FIG. 1;

FIG. 2B is a back view of the cover of the embodiment in FIG. 1; and

FIG. 3 is an assembly schematic diagram of the laptop computer display of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

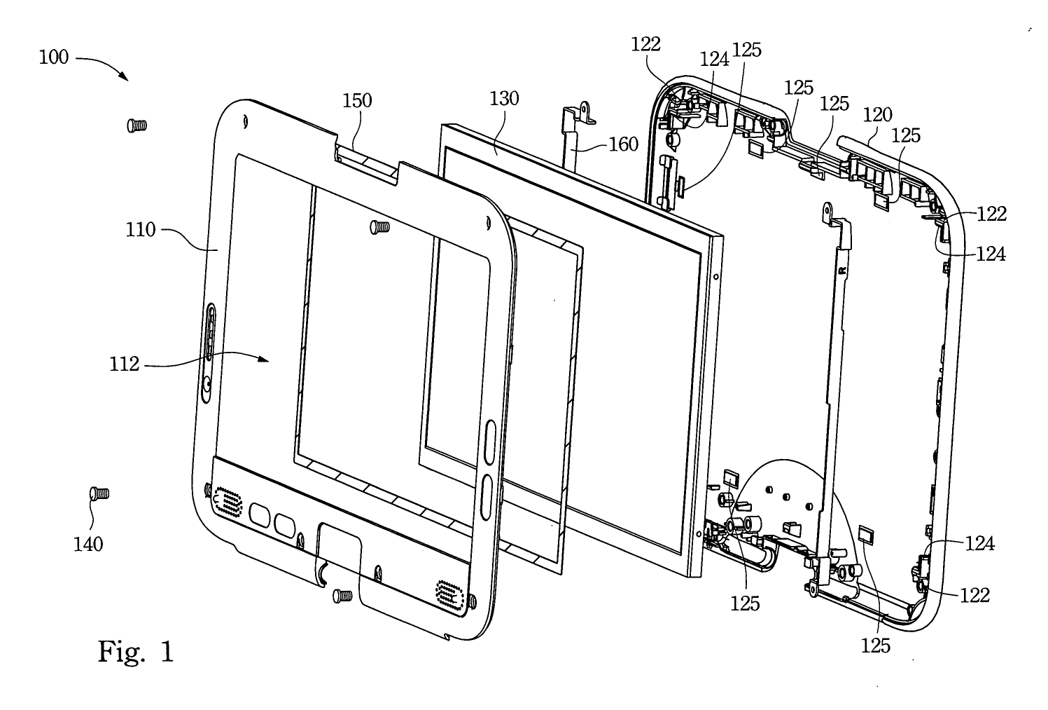

Refer to FIG. 1. FIG. 1 is an explosion diagram of an embodiment of the laptop computer display of the invention. The laptop computer display 10 includes a bezel 110, a cover 120, a display panel 130 disposed between the bezel 110 and the cover 120, and plural screws 140. The bezel 110 has an opening 112 to expose the display panel 130. The screws 140 are used to fasten the bezel 110 and the cover 120, and the display panel 130 is fixed between the bezel 110 and the cover 120.

The cover 120 has plural L-shaped plastic structures 122 and plural L-shaped rubber structures 124 formed on the L-shaped plastic structures 122. The L-shaped rubber structures 124 are formed inside of the L-shaped plastic structures 122. The L-shaped rubber structures 124 are disposed corresponding to the corners of the display panel 130. The L-shaped rubber structures 124 couple to the corner of the display panel 130 to fix the display panel 130 on the cover 120 and provide cushion function. The laptop computer display 100 further includes plural rubber bars 125 disposed on the inner surface of the cover 120. The rubber bars 125 touch the display panel 130 for shockproof.

The laptop computer display 100 may optionally include a cushion 150 disposed between the bezel 110 and the display panel 130. The cushion 150 can be made of rubber and ring-shaped. Thus, the cushion 150 can absorb the shock of the display 100 and provide a space for pre-compression, so that the display panel 130 can be clamped between the cover 120 and the bezel 110 firmly. The cushion 150 can further seal the space between the bezel 110 and the cover 120 to make the display waterproof.

The laptop computer display 100 can further include two panel brackets 160. The panel brackets 160 are disposed at opposite sides of the display panel 130 and are fixed between the bezel 110 and the cover 120. The panel brackets 160 are made of metal, such as stainless steel, to further enhance the structure strength of the display 100 and prevent the display panel 130 from bending damage.

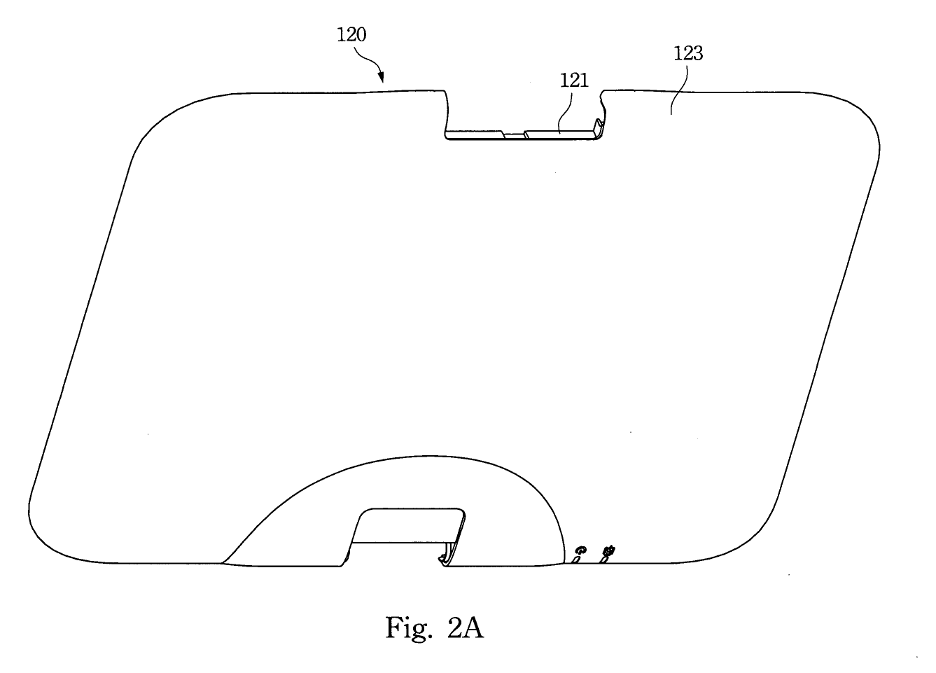

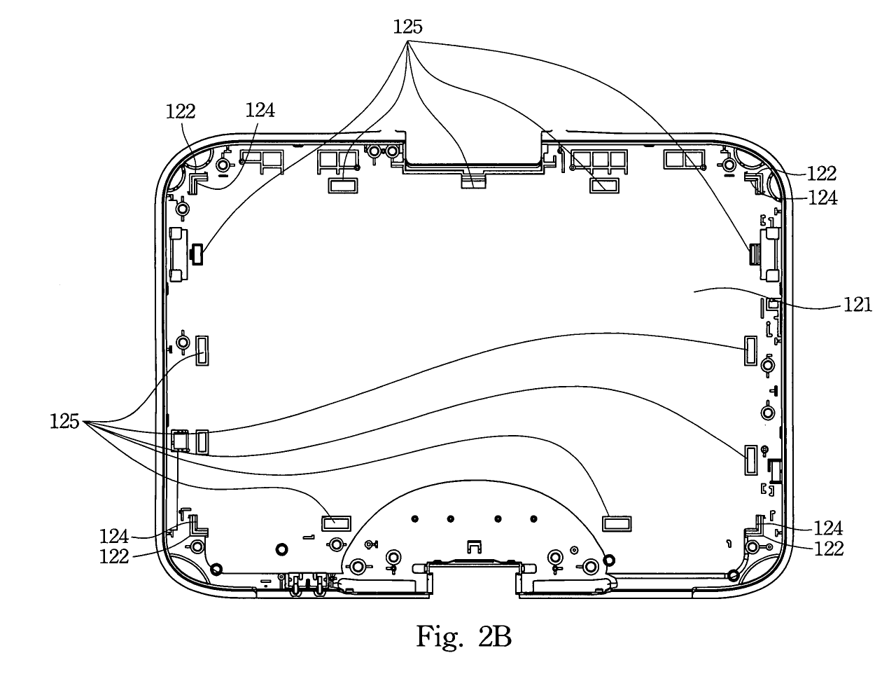

Refer to FIG. 2A and FIG. 2B. FIG. 2A is a front view of the cover of the embodiment in FIG. 1. FIG. 2B is a back view of the cover of the embodiment in FIG. 1. The cover 120 includes a plastic casing 121 and a rubber layer 123. The plastic casing 121 has an inner surface (see FIG. 2B) and an outer surface (see FIG. 2A). The rubber layer 123 is disposed to cover the whole outer surface of the plastic casing 121 to absorb shock force.

Several L-shaped plastic structures 122 are disposed on the inner surface of the cover 120 to define a rectangle area for locating the display panel 130 (see FIG. 1) within. The L-shaped rubber structures 124 are formed inside of the L-shaped plastic structures 122 corresponding to the corners of the display panel 130. The L-shaped rubber structures 124 are designed to be slightly deformed due to the interference when the display panel 130 is assembled, so that the display panel 130 is firmly fixed by the L-shaped rubber structures 124.

The rubber bars 125 could be optionally disposed, between the display panel 130 and the plastic casing 121, on the inner surface of the cover 120 to provide additional cushion space for shockproof.

Those rubber structures such as the L-shaped rubber structures 124, the rubber bars 125, and the rubber layer 123 can be formed on the plastic casing 121 by a coinjection molding process or double-injection molding, thus the L-shaped rubber structures 124, the rubber bars 125, the rubber layer 123, and the plastic casing 121 can be formed integrally in a single piece. The L-shaped rubber structures 124 and the rubber bars 125 are extending from the rubber layer 123, namely, there are plural holes (not shown) penetrating the plastic casing 121, and the rubber layer 123 can be connected to the L-shaped rubber structures 124 and the rubber bars 125 via the holes to enhance the shockproof ability

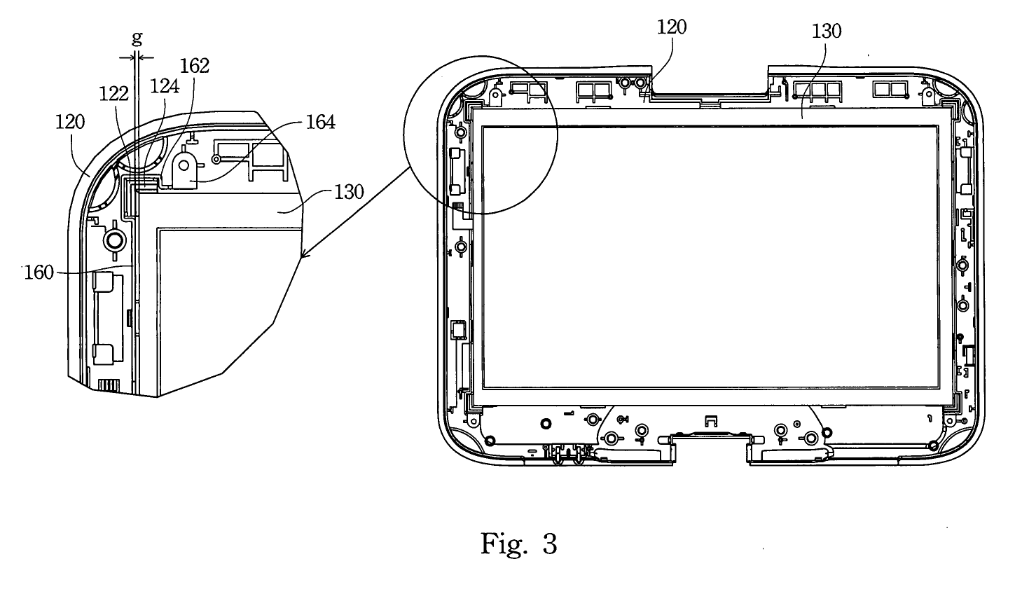

Refer to FIG. 3. FIG. 3 is an assembly schematic diagram of the laptop computer display of the invention. The L-shaped plastic structures 122 and the L-shaped rubber structures 124 formed thereon can define the rectangle area for locating and fixing the display panel 130. The material of the L-shaped plastic structures 122 is harder than the material of the L-shaped rubber structures 124. The L-shaped plastic structures 122 made of hard material can provide better support to position the display panel 130. The L-shaped rubber structures 124 made of soft material are disposed between the L-shaped plastic structures 122 and the display panel 130, and the L-shaped rubber structures 124 would be slightly deformed due to interference when the display panel 130 couple to the L-shaped rubber structures 124, thus the display panel 130 can be fixed by coupling to the L-shaped rubber structures 124 and the L-shaped plastic structures 122.

The panel brackets 160 are used for only preventing the display panel 130 from bending damage but not for positioning the display panel 130. The panel brackets 160 do not touch the display panel 130 directly, however, a gap g is formed between each panel bracket 160 and the display panel 130. In one embodiment, the width of the gap g is at least 1 mm. Each panel bracket 160 has two bending portions 162 disposed on opposite ends used to be coupled to the L-shaped plastic structures 122. Each panel bracket 160 has at least one screwing portion 164. The screws 140 (see FIG. 1) pass through the screwing portions 164 to fix the panel brackets 160 on the cover 120.

Accordingly, the prevent invention provided the following advantages. The rubber layer and the rubber bars formed on the cover can absorb the external shock. The rubber bars and the cushion can be the damping structures of the display panel. The display panel can be fixed by being coupled to the L-shaped plastic structures and the L-shaped rubber structures. The L-shaped rubber structures can provide the display shockproof ability. The cushion disposed between the bezel and the display panel can provide shockproof ability and seal the space between the bezel and the display panel for waterproof. The rubber layer, the L-shaped rubber structures, and the rubber bars are formed integral via the holes of the cover to enhance the shockproof ability of the laptop computer display.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A laptop computer display comprising:
a cover comprising:
a plastic casing having an inner surface, an outer surface, and a plurality of L-shaped plastic structures disposed on the inner surface,
a rubber layer disposed on the outer surface, and
a plurality of rubber structures disposed on the inner surface, wherein the rubber structures comprise a plurality of L-shaped rubber structures formed inside the L-shaped plastic structures;
a display panel disposed on the inner surface, wherein the L-shaped rubber structures are disposed corresponding to a plurality of corners of the display panel to couple to the display panel;
a bezel having an opening to expose the display panel;
a cushion disposed between the cover and the bezel; and
a plurality of screws for screwing the cover and the bezel.

2. The laptop computer display of claim 1, further comprising two panel brackets disposed at opposite sides of the display panel, wherein each panel bracket has two bending portions formed on opposite ends to couple to the L-shaped plastic structures.

3. The laptop computer display of claim 2, wherein a gap is formed between each panel bracket and the display panel.

4. The laptop computer display of claim 3, wherein each panel bracket comprises at least one screwing portion, and the screws screw the panel brackets on the cover.

5. The laptop computer display of claim 1, wherein the rubber structures comprise a plurality of rubber bars disposed on the inner surface and touching the display panel.

6. The laptop computer display of claim 1, wherein the rubber structures connect to the rubber layer.

7. A laptop computer display comprising:
a cover comprising:
a plastic casing having an inner surface and an outer surface,
a plurality of L-shaped plastic structures disposed on the inner surface, and
a plurality of rubber structures disposed on the inner surface, wherein the rubber structures comprise a plurality of L-shaped rubber structures formed inside the L-shaped plastic structures;
a display panel disposed on the inner surface, wherein the L-shaped rubber structures are disposed corresponding to a plurality of corners of the display panel to couple to the display panel;
a bezel having an opening to expose the display panel; and
a plurality of screws for screwing the cover and the bezel.

8. The laptop computer display of claim 7, further comprising two panel brackets disposed on opposite sides of the display panel, wherein each panel bracket has two bending portions formed on opposite ends to couple to the L-shaped plastic structures, and a gap is formed between each panel bracket and the display panel.

9. The laptop computer display of claim 7, wherein the rubber structures comprise a plurality of rubber bars disposed on the inner surface and touching the display panel.

10. The laptop computer display of claim 7, further comprising a rubber layer disposed on the outer surface of the plastic casing, wherein the rubber structures connect to the rubber layer.
